(19) United States
(12) Patent Application Publication
(10) Pub. No.: US 2025/0316448 A1
(43) Pub. Date: Oct. 9, 2025

(54) HETEROGEOUS NEGATIVE ION SOURCE BASED UPON HYDROGEN PLASMA

(71) Applicant: Applied Materials, Inc., Santa Clara, CA (US)

(72) Inventor: Klaus BECKER, Kensington, NH (US)

(73) Assignee: Applied Materials, Inc., Santa Clara, CA (US)

(21) Appl. No.: 18/628,393

(22) Filed: Apr. 5, 2024

(51) Int. Cl. H01J 37/317; H01J 37/32

(52) U.S. Cl. CPC H01J 37/3171; H01J 37/32449; H01J 37/32669; H01J 37/32688

(57) ABSTRACT

An ion source assembly. The ion source assembly may include a hydrogen gas source, and an ion source, comprising a plasma chamber, coupled to receive a first flow of hydrogen gas from the hydrogen gas source, the ion source comprising a set of components to generate a plasma within the plasma chamber. The plasma may include a first portion of negative hydrogen ions. The ion source assembly may include a second gas source, separate from the hydrogen gas source, the second gas source being coupled to deliver to the plasma chamber a second flow of a second gas, different from the hydrogen gas. As such, the set of components of the ions source may be further arranged to generate a second portion of second negative ions, different than the first portion of negative hydrogen ions, by reacting the second gas with the first portion of negative hydrogen ions.

### FIELD

The present embodiments relate to negative ion sources, and in particular, negative ion sources for ion implanters.

### BACKGROUND

Ion implanters are widely used in electronic device fabrication, including semiconductor manufacturing to control device properties. In a typical ion implanter, ions generated from an ion source are directed as an ion beam through a series of beam-line components that may include an analyzing magnet and a plurality of electrodes that provide electric fields to tailor the ion beam properties. The analyzing magnet selects desired ion species, and filters out contaminant species and ions having undesirable energies. Suitably shaped electrodes may modify the energy and the shape of an ion beam.

For high-energy ion implantation, typically 100 keV or greater, tandem acceleration may be used to accelerate ions to a desired high energy. A tandem accelerator may be disposed along the beam line of an ion implanter in order to generate sufficiently high energy to implant ions into a substrate at desired depths. In a tandem acceleration process, an electrostatic accelerator accelerates negative ions generated in a special ion source from ground potential up to a positive high-voltage terminal. The electrons on the negative ions may then be stripped by passage through a charge exchange region (referred to as a “stripper”). The resulting positive ions are again accelerated as they pass to ground potential from the high negative potential. The ions emerge from the tandem accelerator with twice the energy of the high positive voltage applied to the tandem accelerator.

In present day technology, negative ions that are sent to the tandem accelerator for acceleration may be generated in a charge exchange process. A charge exchange medium such as a heated magnesium source is used to generate a source of electrons for negatively ionizing a desired species for implantation. Such charge exchange sources may be especially suitable for generating negative hydrogen ions and negative helium ions, for example. A disadvantage of using a magnesium source for charge exchange to generate negative ions is the relative flammability of magnesium deposits that may develop during implanter use, and the extra set-up time needed to heat the heated magnesium charge exchange source.

With respect to these and other considerations the present embodiments are provided.

### BRIEF SUMMARY

In one embodiment, an ion source assembly is provided. The ion source assembly may include a hydrogen gas source, and an ion source, comprising a plasma chamber, coupled to receive a first flow of hydrogen gas from the hydrogen gas source, the ion source comprising a set of components to generate a plasma within the plasma chamber. The plasma may include a first portion of negative hydrogen ions. The ion source assembly may include a second gas source, separate from the hydrogen gas source, the second gas source being coupled to deliver to the plasma chamber a second flow of a second gas, different from the hydrogen gas. As such, the set of components of the ions source may be further arranged to generate a second portion of second negative ions, different than the first portion of negative hydrogen ions, by reacting the second gas with the first portion of negative hydrogen ions.

In another embodiment, an ion implanter may include a negative ion source assembly, to generate a beam of heterogeneous negative ions. The negative ion source assembly may include a hydrogen gas source, and an ion source, comprising a plasma chamber, coupled to receive a first flow of hydrogen gas from the hydrogen gas source, the ion source comprising a set of components to generate a plasma comprising a first portion of negative hydrogen ions. The negative ion source assembly may further include a second gas source, separate from the hydrogen gas source, the second gas source being coupled to deliver to the plasma chamber a second flow of a second gas, different from the hydrogen gas. As such, the set of components of the ion source may be further arranged to generate a second portion of second negative ions, different than the first portion of negative hydrogen ions, by reacting the second gas with the first portion of negative hydrogen ions. The ion implanter may also include an analyzer, arranged to receive the beam of heterogeneous negative ions and output a beam of second negative ions, and a tandem accelerator, arranged to receive the beam of second negative ions at a first ion energy, and output a beam of positive ions at a second ion energy, greater than the first ion energy.

In a further embodiment, a method of generating a negative ion beam is provided. The method may include providing a first flow of hydrogen gas to a plasma chamber of an ion source, and providing a second flow of a second gas, different than the hydrogen gas, to the plasma chamber of the ion source, wherein a heterogeneous gas is formed in the plasma chamber. The method may further include generating a set of negative hydrogen ions in the ion source in the presence of the heterogeneous gas, and extracting a heterogeneous negative ion beam from the ion source at a first energy, wherein the heterogeneous negative ion beam comprises a set of.

### BRIEF DESCRIPTION OF DRAWINGS

FIG. 1 shows an exemplary system in accordance with the present disclosure;

FIG. 2 depicts an exemplary ion source assembly and analyzer, according to some embodiments of the present disclosure;

FIG. 3 depicts details of an exemplary ion source, according to some embodiments of the present disclosure; and

FIG. 4 shows an exemplary process flow, according to embodiments of the disclosure.

### DETAILED DESCRIPTION

The present embodiments will now be described more fully hereinafter with reference to the accompanying drawings, where some embodiments are shown. The subject matter of the present disclosure may be embodied in many different forms and are not to be construed as limited to the embodiments set forth herein. Instead, these embodiments are provided so this disclosure will be thorough and complete, and will fully convey the scope of the subject matter to those skilled in the art. In the drawings, like numbers refer to like elements throughout.

The present embodiments provide novel ion source assemblies that employ hydrogen plasmas to generate negative ions of a different species than hydrogen. Such ion source assemblies may be advantageously employed, for example, to generate a negative helium ion beam for use in a high energy implanter that is based upon a tandem accelerator. As detailed in the embodiments to follow, a negative helium ion beam or negative ion beam of other species may be obtained by first generating in a plasma chamber a heterogeneous plasma including negative hydrogen ions and negative ions of a second species, extracting a heterogeneous negative ion beam from the plasma chamber, and then filtering the heterogeneous negative ion beam to obtain a negative ion beam of a targeted species for feeding to a tandem accelerator.

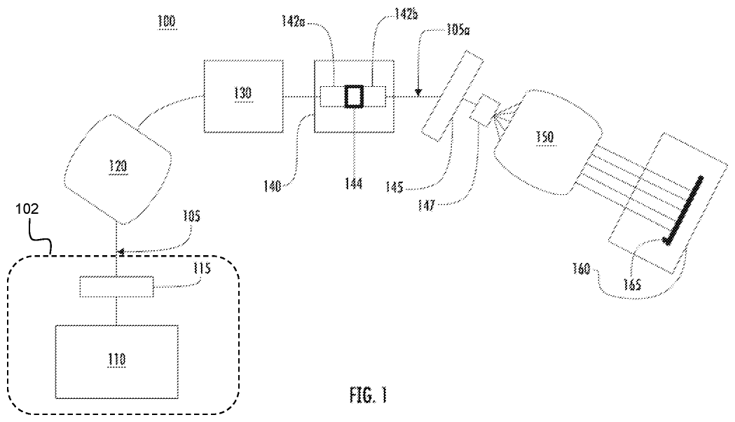

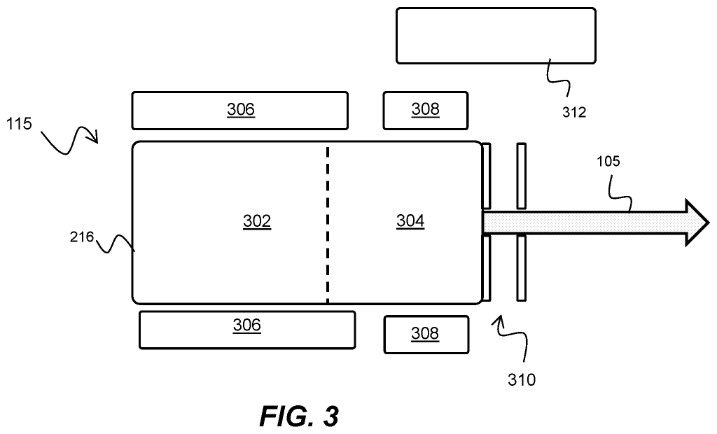

FIG. 1 illustrates a block diagram of an exemplary high-energy ion implanter system, referred to herein as system 100. Although the system 100 is shown having a limited number of elements in a certain topology, it may be appreciated that-system 100 may include more or less elements in alternate topologies as desired for a given implementation. An ion source assembly 102 is provided, including a source gas assembly 110 that is coupled to provide gases to an ion source 115. As detailed below, the ion source 115 is configured to generate negative ions of a particular species or of more than one species, based on the introduction of a feed gas or feed gases supplied by the source gas assembly 110. The feed gas is introduced into the ion source 115 and is ionized to generate a plasma including negative ions. In various embodiments, the ion source 115 may be a multi-cusp magnet ion source that is suitable to generate negative hydrogen ions, as well as negative ions of other species as detailed with respect to FIG. 3 to follow.

A negative ion beam 105 may be extracted from the ion source 115 through an extraction aperture by a biased extraction electrode assembly (not separately shown).

The negative ion beam 105 may then be directed through a mass analyzer 120, such as a mass analyzer magnet. The mass analyzer 120 may include a resolving magnet, which magnet functions to pass just ions having the desired mass and energy to a resolving aperture. In particular, mass analyzer 120 may include a curved path where the negative ion beam 105 is exposed to an applied magnetic field such that just the ions with a desired mass-to-charge ratio are able to travel through a mass resolving slit downstream of the mass analyzer 120.

The negative ion beam 105 may be directed through a lens 130, which lens may include an Einzel lens or a quadrupole lens, for example, to focus the negative ion beam 105 for transmission through a tandem accelerator 140. To this point, the negative ion beam 105 may be deemed to be a low energy ion beam having an energy in the range of a few keV to a few tens of keV, in some embodiments. Tandem accelerator 140 is coupled to receive the negative ion beam 105 (e.g., the low energy ion beam) and accelerate the negative ion beam 105 to energies in the range of several hundred keV to several thousand keV (i.e. MeV), resulting in a high-energy ion beam 105A. The tandem accelerator 140 may be arranged similarly to known tandem accelerators according to various embodiments of the disclosure. For example, the tandem accelerator may include a low-energy accelerator tube 142A, a stripper 144, and a high-energy accelerator tube 142B. In general, each of the low-energy accelerator tube 142A and the high-energy accelerator tube 142B may contain a number of electrodes separated by insulating rings. A positive high voltage may be applied by a high voltage power supply to a terminal located on the end of the low-energy accelerator tube 142A and a terminal located on the end of the high-energy accelerator tube 142B. These two terminals are located on the ends adjacent to the stripper 144. The supplied positive high voltage may be delivered from the terminals to the highest voltage electrodes of the low-energy accelerator tube 142A and the high-energy accelerator tube 142B. Adjacent electrodes may be interconnected by high value resistors, which resistors distribute the applied voltage among the electrodes. The other ends of the low-energy accelerator tube 142A and the end of the high-energy accelerator tube 142B may be maintained at ground potential.

The stripper 144 is disposed between the low-energy accelerator tube 142A and the high-energy accelerator tube 142B. The stripper 144 converts ions in the negative ion beam 105 from a negative charge to a positive charge. One manner of conversion from negative charge to positive charge is accomplished by the introduction of a gas such as, for example, argon, in the path of the negative ion beam 105. During operation, the negative ion beam 105 is injected into the tandem accelerator 140, accelerated through the low-energy accelerator tube 142A, converted to a positive ion beam in the stripper 144, and accelerated further in the high-energy accelerator tube 142B. During operation, as the negative ion beam 105 passes through the stripper 144, the negatively charged ions collide with the particles in the gas and electrons are “stripped” from the negatively charged ions, changing the negative ions to positively charged ions.

Once the negative ion beam 105 passes into the tandem accelerator 140, is accelerated, and changed to a positive ion beam, the resulting ion beam exits the tandem accelerator as a high-energy ion beam 105A, which ion beam is now positively charged. The high-energy ion beam 105A may be supplied to filter 145. The filter 145 may be a magnet that filters away the ions with undesired energy from the high-energy ion beam 105A. In some embodiments, a scanner 147 may be provided to scan the high energy ion beam 105A back and forth in a scan plane. A collimator 150, which component may include a collimator magnet, may be positioned downstream of the scanner 147 and energized to deflect ion beamlets of the high-energy ion beam 105A in accordance with the strength and direction of an applied magnetic field to collimate the beam and direct the ion beam towards an end station 160. The collimator 150 may be provided to ensure that the high-energy ion beam 105A is incident on a target substrate supported by platen 165 within end station 160 at a constant angle across the surface of the substrate. The ions of high-energy ion beam 105A lose energy when the ions collide with electrons and nuclei in the target substrate and come to rest at a desired depth within the substrate based on the acceleration energy. The end station 160 may support one or more substrates on platen 165 in the path of high-energy ion beam 105A. The end station 160 may also include additional components known to those skilled in the art. For example, end station 160 may typically include automated handling equipment for introducing target substrates into a processing chamber and for removing such substrates after ion implantation.

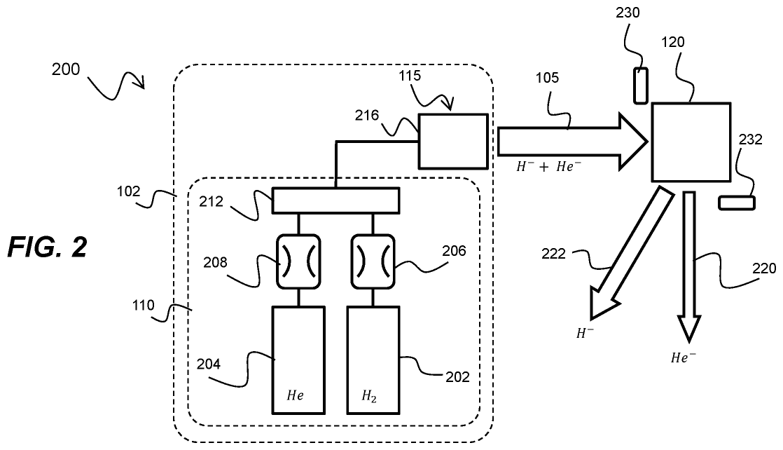

FIG. 2 depicts an exemplary ion source assembly and analyzer, according to some embodiments of the present disclosure. The ion source assembly 200 may include a source gas assembly 110 and ion source 115. The source gas assembly may include a hydrogen gas source 202 and a second gas source 204, separate from the hydrogen gas source 202. The hydrogen gas source 202 may be coupled to deliver a first flow of hydrogen gas to a plasma chamber 216 of the ion source 115, while the second gas source 204 is coupled to deliver a second flow of a second gas to the plasma chamber 216. In some embodiments the second gas source 204 may be a helium gas source, coupled to deliver a flow of helium gas to the plasma chamber 216. As shown in FIG. 2, the source gas assembly may further include a first valve 206 and a second valve 208 to regulate flow of the hydrogen gas and second gas, respectively. These gases may be supplied to the ion source 115 via a manifold 212, for example, where mixing of the different gases may take place before entry into the ion source 115. Thus, according to various embodiments of the disclosure, a flow of hydrogen gas, as well as a flow of a second gas, such as He, may be provided simultaneously to the plasma chamber 216, which circumstance facilitates reaction of species from the second gas with hydrogen ions as detailed below.

As detailed further with respect to FIG. 3, the ion source 115 may include a set of components to generate a plasma comprising a first portion of negative hydrogen ions. As discussed further below, the ion source 115 may be further configured to generate a second portion of second negative ions within the plasma chamber 216, different than the first portion of negative hydrogen ions, by reacting the second gas with the first portion of negative hydrogen ions.

In operation, the ion source assembly 200 may output a beam of heterogeneous negative ions. In FIG. 2 the beam of heterogeneous negative ions is depicted as a variant of the negative ion beam 105, discussed earlier with respect to FIG. 1. In this example, the term “heterogeneous negative ions” may refer to a collection of negative ions that include negative ions derived from at least two different species, where a first portion of negative ions may be negative hydrogen ions. A second portion of negative ions that make up the negative ion beam 105 may be helium ions, argon ions, or NH⁻ ions, according to some non-limiting embodiments of the disclosure.

Advantageously, the ion source assembly 200 may be coupled with a mass analyzer 120, described above with respect to FIG. 1, in order to generate an analyzed negative ion beam 220. The analyzed negative ion beam 220 may include a set of negative ions derived from the second gas of second gas source 204, such as negative helium ions. As such, by virtue of operation of the mass analyzer, the negative hydrogen ions 222, forming a first portion of the negative ion beam 105, may be removed from the analyzed negative ion beam 220, so that the analyzed negative ion beam 220 may be provided to a tandem accelerator for further treatment without the set of negative hydrogen ions. This architecture provides a novel approach to generating a negative ion beam of non-hydrogen negative ions, by generating negative hydrogen ions in the ion source 115, as a pathway for forming the non-hydrogen negative ions.

FIG. 3 depicts details of an exemplary ion source, according to some embodiments of the present disclosure. In this example, the ion source depicted may be considered to be a variant of the ion source 115. As shown in FIG. 3, the ion source 115 may be a multi-cusp-magnet ion source that is suitable to generate negative hydrogen ions. In particular embodiments, the ions source 115 may be a commercially available multi-cusp-magnet ion source used to generate negative hydrogen ions. While negative hydrogen ion sources have not been developed for beamline ion implanters, negative hydrogen ion sources have been developed for cyclotrons and related technology. Accordingly, in some embodiments of the present disclosure, the ion source 115 may be a commercially available negative hydrogen ion source that is installed as part of in an ion source assembly 200 in order to generate a heterogeneous negative ion beam for use in a beamline ion implanter.

As depicted in FIG. 3, the ion source 115 may include a plasma chamber 216, and magnet assembly 306, disposed to generate a plasma in a high temperature plasma region 302 of the plasma chamber 216. The ion source 115 may further include a filter magnet assembly 308, disposed around a low temperature plasma region 304 of the plasma chamber 216. Note that the high temperature plasma region 302 and the low temperature plasma region 304 will form in a common chamber, where the low temperature plasma region 304 is disposed further away from a filament used to generate electrons (not shown). Particles in the low temperature plasma region 304 will accordingly have lower energy on average than particles in the high temperature plasma region 302.

The ion source 115 may also include an extraction assembly 310 and extraction power supply 312, arranged to provide suitable voltage on electrodes therein to extract the negative ion beam 105 from plasma chamber 216.

In operation, the ion source 115 may generate negative hydrogen ions by a series of known reactions that may take place within the plasma chamber 216. For example, H₂ gas may react with electrons generated in the high temperature plasma region 302 to form negatively charged excited molecular ions

$${H}_{2}^{* -} .$$

As indicated by the star symbol, these negatively charged hydrogen molecular ions may be in an excited state, and may thus subsequently decay into a more stable species, such as negative atomic hydrogen ions, meaning H⁻. As noted, commercial sources are available to generate a plurality of negative charged molecular hydrogen ions,

$${H}_{2}^{* -} ions ,$$

that are critical precursors for generating H⁻ ions. In particular these negatively charged molecular hydrogen ions may dissociate into an energetic hydrogen neutral and an elemental hydrogen negative ion, H⁻. In accordance with embodiments of the disclosure, a second gas, such as helium (He) may be provided to the plasma chamber 216, together with hydrogen gas (H₂). When the ion source 115 is energized to generate excited negative molecular hydrogen ions, these negatively charged molecular hydrogen ions may also react with the He gas in the plasma chamber 216 to generate negative helium ions, He*⁻ ions, in addition to H⁻ ions.

With respect to embodiments where the ion source is a commercially available negative hydrogen ion source, such as source produces negative hydrogen ions in several steps that include, among others, production of negative ionized hydrogen molecules in an excited state

$$( {H}_{2}^{* -} ) .$$

Such molecules are unstable and often dissociate into H⁰ and H⁻ which dissociation process produces the desired H⁻ under normal operation. The present inventor has recognized

$${H}_{2}^{* -}$$

and H⁻ can also transfer the excess electron of said negative ions to another atom, as long as that atom has positive electron affinity. As an example, He in the excited state, He*, has an electron affinity of +0.078 eV, so He* can accept the electron to form He*⁻. Initial production of the excited state He* requires approximately 20 eV excitation energy to be imparted into a ground state helium atom. That excitation energy may be delivered by collision with other species of a plasma in a suitable ion source, such as hot electrons. In this manner a commercial ion source for H⁻ or specialized ion source may be used to produce He*⁻. Note that the introduction of He gas into the plasma to some extent disrupts the normal operation that produces

$${H}_{2}^{* -}$$

and H⁻, so that in accordance with embodiments of the disclosure, the relative flow of He gas is relatively lower, typically less than 20% of total gas flow by volume.

Accordingly, by generating a sufficient density of

$${H}_{2}^{* -} ions$$

and/or a suitable concentration of H− ions, in the plasma chamber 216, and by providing a suitable flow of He gas into the plasma chamber 216 at the same time, a suitable current of He*⁻ ions may be generated, extracted, and analyzed, to form the analyzed negative ion beam 220. Note that He*⁻ has an excited state with a lifetime of 345 ms, which lifetime is sufficient for transport from the ion source 115 to tandem accelerator 140 before decay. Moreover, in other embodiments, the

$${H}_{2}^{* -} ions$$

that may be generated in the ion source 115 may be employed to generate negative argon ions in the plasma chamber 216. In this regard, an excited argon ion, Ar− exhibits a lifetime of 0.26 ms, which lifetime is still sufficient to allow transport to the tandem accelerator 140 at ion energies in the keV range for the negative ion beam 105 and analyzed negative ion beam 220.

In other embodiments, the same approach of generating

$${H}_{2}^{* -} ions$$

in the plasma chamber 216 may be used to generate negative molecular ions, such as NH. In this latter case, the hydrogen portion of the NH⁻ molecule will be stripped in the tandem accelerator 140, so that just a beam of positive nitrogen ions will be output by the tandem accelerator 140.

Referring again to FIG. 2, a suitable flow rate for hydrogen gas and flow rate for a second gas, such as helium gas, may be readily identified by varying flow of one or more gases to the manifold 212, in order to determine the effect on negative helium ion current extracted from the ion source 115, for example. In one example, the flow rate of helium gas may be fixed at a designated value, such as in the range of a few tenths of one sccm to a couple sccm. At this fixed flow rate of helium gas, according to some non-limiting embodiments, the flow rate of hydrogen gas may be varied in suitable increments, such as 0.5 sccm increments, from a lower value of say, 0.5 sccm to an upper value of say 10 sccm. The resulting ion beam current may then be measured, for example, for negative ion beam 105, using a detector 230, located before the mass analyzer 120, and using a detector 232, located after the mass analyzer 120, for measuring the analyzed negative ion beam 220. Note that the exact construction and parameters used in mass analyzer 120 may be arranged according to the ions to form negative ion beam 220. Thus, for the production of negative helium ions, the mass analyzer 120 may be arranged to filter out hydrogen negative ions while transporting negative atomic helium ions. In this manner, a suitable recipe for hydrogen flow and helium flow may be established that generates a targeted amount of negative helium ion current. Note that other parameters of an ion implanter will also be adjusted accordingly in order to improve helium ion current, including extraction voltage at the ion source 115, and setting for the mass analyzer 120.

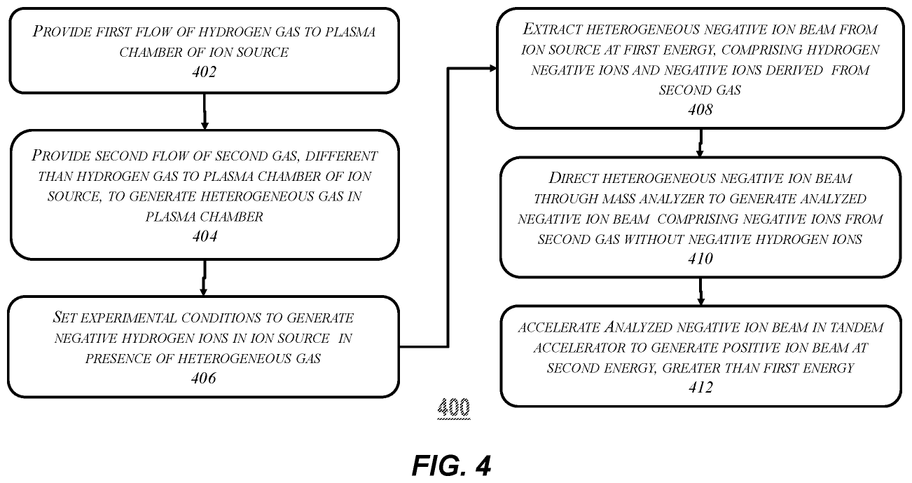

FIG. 4 shows an exemplary process 400, according to embodiments of the disclosure. At block 402, a first flow of hydrogen gas is provided to a plasma chamber of an ion source. In some embodiments, the ion source may be a multi-cusp ion source, arranged to generate a multi-cusp magnetic field.

At block 404, a second flow of a second gas, different than the hydrogen gas, is provided to the plasma chamber of the ion source, in order to generate a heterogeneous gas in plasma chamber. In some non-limiting examples, the second gas may be helium gas.

At block 406 experimental conditions for the ion source are set in order to generate negative hydrogen ions in the multi-cusp ion source in the presence of the heterogeneous gas. As such, the experimental conditions may generate a plurality of negative charged molecular hydrogen ions,

$${H}_{2}^{* -} ions ,$$

that may then generate H⁻ ions. In the presence of heterogeneous gas, including a second gas, such as helium (He), the negatively charged molecular hydrogen ions may also react with the He gas in the ion source to generate negative helium ions, He*⁻ ions.

At block 408, a heterogeneous negative ion beam is extracted from the ion source at a first energy, where the heterogeneous negative ion beam includes hydrogen negative ions and negative ions derived from the second gas, such as negative helium ions.

At block 410, the heterogeneous negative ion beam is directed through a mass analyzer to generate an analyzed negative ion beam comprising negative ions that are derived from the second gas without the negative hydrogen ions.

At block 412, the analyzed negative ion beam is accelerated in a tandem accelerator to generate a positive ion beam at a second energy, greater than the first energy.

While the above embodiments have detailed the use of a multi-cusp ion source to generate a heterogeneous ion beam, for example, that includes negative helium ions, in further embodiments, other configurations of an ion source are possible. A common feature of such ion sources will be the provision of suitable species to excite and ionize a desired implant species, such as He⁰ being excited and ionized to He*⁻. Examples of such suitable species include H⁻ or

$${H}_{2}^{* -}$$

or cold electrons or any combination thereof. Thus, the present embodiments cover any suitable ion source capable of generating such suitable species in conjunction with providing He gas, for example.

Moreover, while the above embodiments have focused on implant species such as helium that are capable of binding electrons just in an excited state, other embodiments of negative ion sources may include negative ion sources that generate negative ion species from precursors that are capable of binding electrons in the ground state. Such negative ion species include carbon, boron, phosphorous, arsenic, and so forth. In such latter examples, generation of such negative ion species can eliminate the need for a vapor based charge exchange component of a beamline ion implanter.

Advantages provided by the present embodiments are multifold. As a first general advantage, the present embodiments facilitate the construction beamline ion implanters based on tandem accelerators that do not need a charge exchange oven to transfer negative charge to a positive ion, such as helium. This general advantage leads to other advantages including the elimination of handling of dangerous metals during charge exchange over service, such as alkali or alkaline earth metals. Another related advantage is the elimination of contamination risk from alkali or alkaline earth metals for semiconductor substrates being implanted by the beamline implanter. A further related advantage is the reduction in manufacturing cost and implanter footprint due to the absence of the charge exchange oven. Another advantage provided by the present embodiments is the faster startup of the ion implanter from a cold state, because there is no charge exchange oven that needs to heat up and stabilize oven temperature. For instance, heating up and stabilization can take up to an hour for a magnesium oven operating at over 400° C. An additional contemplated advantage is the ability to generate relatively higher beam current, using an ion source assembly of the present embodiments, because the electron transfer from

$${H}_{2}^{* -}$$

and H⁻ to He* is more efficient than from metal vapor. In particular, the binding energy of the electron for negative ions is lower than for neutral atoms, so transfer will be easier. This statement is evidenced by comparison of the energy of removal of the extra electron from H⁻, H⁻⇒H⁰+e⁻: 0.75 eV, in comparison to removal of an electron from a neutral cesium atom—Cs⁰⇒Cs⁺+e⁻: 3.89 eV, where cesium is the chemical element having lowest ionization energy.

The present disclosure is not to be limited in scope by the specific embodiments described herein. Indeed, other various embodiments and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, the present disclosure has been described herein in the context of a particular implementation in a particular environment for a particular purpose, yet those of ordinary skill in the art will recognize the usefulness is not limited thereto and the present disclosure may be beneficially implemented in any number of environments for any number of purposes. Thus, the claims set forth below are to be construed in view of the full breadth and spirit of the present disclosure as described herein.

What is claimed is:

1. An ion source assembly, comprising:
a hydrogen gas source;
an ion source, comprising a plasma chamber, coupled to receive a first flow of hydrogen gas from the hydrogen gas source, the ion source comprising a set of components to generate a plasma within the plasma chamber, comprising a first portion of negative hydrogen ions; and
a second gas source, separate from the hydrogen gas source, the second gas source being coupled to deliver to the plasma chamber a second flow of a second gas, different from the hydrogen gas,
wherein the set of components of the ion source are further arranged to generate a second portion of second negative ions, different than the first portion of negative hydrogen ions, by reacting the second gas with the first portion of negative hydrogen ions.

2. The ion source assembly of claim 1, the second portion of second negative ions comprising negative helium ions.

3. The ion source assembly of claim 1, the second portion of second negative ions comprising negative argon ions or NH⁻ ions.

4. The ion source assembly of claim 1, the second portion of second negative ions comprising carbon ions, boron ions, phosphorous ions, or arsenic ions.

5. The ion source assembly of claim 1, the first portion of negative hydrogen ions comprising negative molecular hydrogen ions.

6. The ion source assembly of claim 1, the plasma chamber comprising a high temperature plasma region to generate a high temperature plasma, and a low temperature plasma region, wherein the second gas source is coupled to deliver the second flow of the second gas to the low temperature plasma region of the plasma chamber.

7. The ion source assembly of claim 1, the ion source being a multi-cusp ion source and further comprising a set of magnets, disposed outside of the plasma chamber, to generate a multi-cusp magnetic field within the plasma chamber.

8. An ion implanter, comprising:
a negative ion source assembly, to generate a beam of heterogeneous negative ions, the negative ion source assembly, comprising:
a hydrogen gas source;
an ion source, comprising a plasma chamber, coupled to receive a first flow of hydrogen gas from the hydrogen gas source, the ion source comprising a set of components to generate a plasma comprising a first portion of negative hydrogen ions;
a second gas source, separate from the hydrogen gas source, the second gas source being coupled to deliver to the plasma chamber a second flow of a second gas, different from the hydrogen gas,
wherein the set of components of the ion source are further arranged to generate a second portion of second negative ions, different than the first portion of negative hydrogen ions, by reacting the second gas with the first portion of negative hydrogen ions;
an analyzer, arranged to receive the beam of heterogeneous negative ions and output a beam of second negative ions; and
a tandem accelerator, arranged to receive the beam of second negative ions at a first ion energy, and output a beam of positive ions at a second ion energy, greater than the first ion energy.

9. The ion implanter of claim 8, the second portion of second negative ions comprising negative helium ions.

10. The ion implanter of claim 8, the second portion of second negative ions comprising negative argon ions or NH⁻ ions.

11. The ion implanter of claim 10, wherein the tandem accelerator is configured to output the beam of positive ions as positive nitrogen ions, without hydrogen.

12. The ion implanter of claim 8, the second portion of second negative ions comprising carbon ions, boron ions, phosphorous ions, or arsenic ions.

13. The ion implanter of claim 8, the plasma chamber comprising a high temperature plasma region to generate a high temperature plasma, and a low temperature plasma region, wherein the second gas source is coupled to deliver the second flow of the second gas to the low temperature plasma region of the plasma chamber.

14. The ion implanter of claim 8, the ion source further comprising a set of magnets, disposed outside of the plasma chamber, to generate a multi-cusp magnetic field within the plasma chamber.

15. A method of generating a negative ion beam, comprising:
providing a first flow of hydrogen gas to a plasma chamber of an ion source;
providing a second flow of a second gas, different than the hydrogen gas, to the plasma chamber of the ion source, wherein a heterogeneous gas is formed in the plasma chamber;
generating a set of negative hydrogen ions in the ion source in a presence of the heterogeneous gas; and
extracting a heterogeneous negative ion beam from the ion source at a first energy, wherein the heterogeneous negative ion beam comprising a set of negative atomic hydrogen ions and a set of negative ions derived from the second gas.

16. The method of claim 15, further comprising directing the heterogeneous negative ion beam through a mass analyzer to generate an analyzed negative ion beam, comprising the set of negative ions from the second gas without the set of negative atomic hydrogen ions.

17. The method of claim 16, accelerating the analyzed negative ion beam in a tandem accelerator to generate a positive ion beam at a second energy, greater than the first energy.

18. The method of claim 15, wherein the set of negative ions comprises negative helium ions.

19. The method of claim 15, wherein the set of negative ions comprises negative argon ions, NH⁻ ions, carbon ions, boron ions, phosphorous ions, or arsenic ions.

20. The method of claim 15, wherein the ion source is a multi-cusp ion source.
